(19) United States
(12) Patent Application Publication
(10) Pub. No.: US 2002/0166503 A1
(43) Pub. Date: Nov. 14, 2002

(54) Hybrid crucible susceptor

(75) Inventors: Jan Magras, Bellflower, CA (US); Kim Fjeldsted, Portland, OR (US); Brian Ferguson, Newburgh, OR (US)

Correspondence Address: JOSEPH G CURATOLO, ESQ., RENNER KENNER GREIVE BOBAK TAYLOR & WEBER, 24500 CENTER RIDGE ROAD, SUITE 280, WESTLAKE, OH, 44145, US

(73) Assignee: Hitco Carbon Composites, Inc., Gardena, CA (US)

(21) Appl. No.: 09/803,239

(22) Filed: Mar. 8, 2001

(51) Int. Cl. C30B 15/20; C30B 23/00; C30B 25/00; C30B 28/12; C30B 28/14; C30B 1/00

(52) U.S. Cl. 117/100

(57) ABSTRACT

A crucible susceptor for a crystal growing process for pulling a crystal ingot from a crystal material melt in a crucible, comprises at least one high purity composite component containing a carbon fiber reinforced carbon matrix, said at least one high purity composite component having a total level of metal impurity less than about 10 parts per million; and at least one high purity graphite component, said at least one high purity graphite component having a total level of metal impurity less than about 10 parts per million. A single crystal growing process for pulling a single crystal ingot from a crystal material melt includes providing a crystal material melt in a crucible and intimately supporting the crucible with the crucible susceptor of the present invention. The crucible susceptor disclosed may be used in a Czochralski crystal growing process for pulling a semiconductor ingot from a semiconductor material melt.

### BACKGROUND OF THE INVENTION

This invention relates to a component of a Czochralski process furnace. More particularly, this invention relates to a Czochralski furnace crucible susceptor. Specifically, this invention relates to a Czochralski furnace hybrid crucible susceptor comprising a carbon fiber-reinforced carbon matrix section fitted to a graphite section.

Single crystals are used in a variety of high performance industries. For example, single crystal silicon wafers are used in the semiconductor industry and single crystal sapphire crystals are used in the defense (antenna windows), electronic (light emitting diodes), and general industries (laser scanner windows). Such single crystals are usually made in a high temperature operation.

An example of this is the production of silicon wafers for use in the semiconductor industry by the Czochralski or “CZ” process. In the CZ process, a seed crystal of known orientation is immersed in a molten pool of silicon. This triggers crystallization of the silicon. As the crystal is mechanically pulled upwardly from the pool, the orientation of the solidifying front follows that of the seed crystal. Silicon wafers can be manufactured from the solid ingot by machining and polishing.

Specifically constructed furnaces are used to accurately control the various parameters needed to ensure that high quality crystals of exacting specifications are produced. Several of the key components in these crystal growing furnaces are made from graphite. These include various liners, shields, tubes, crucible susceptors and the like. Graphite has been the material conventionally utilized in such processes due to its high temperature capability and relative chemical inertness.

Disadvantages of graphite include its poor durability brought about by its brittle nature and its tendency to microcrack when exposed to repeated temperature cycles. Such microcracking alters the thermal conductivity of the component which in turn makes accurate temperature control of the crystal melt difficult. In addition, contamination of the melt may occur by the leaching of impurities from the graphite components or from particulates generated by the degradation of the graphite itself.

Semiconductor standards require extremely low levels of impurities in the semiconductor processing system, to allow substantially no impurities to be incorporated into the semiconductor material, as even trace amounts can alter the electronic properties of the semiconductor material.

Further, the deposition of oxides of silicon on graphite parts during the production of the silicon crystal occurs to such an extent that parts must be cleaned on a regular basis and replaced periodically. Replacing worn graphite parts is a time consuming and costly process.

Therefore, there has been a need for the manufacture of components for single crystal growing reactors that have the advantages of graphite without the disadvantages. Such components would enable the more cost effective production of high quality single crystals, including silicon semiconductor wafers.

There have been attempts made to utilize carbon/carbon composites in similar electronic material production processes, in place of graphite furnace components and furniture. U.S. Pat. No. 5,132,145 and corresponding European Patent application 88401031.5 to Valentian disclose a method of making a composite material crucible for use in the Bridgman method for producing single crystals of metallic material semiconductors.

Valentian proposed making a cylindrical crucible for holding a molten sample, from a single wall of carbon fibers or silicon carbide fibers impregnated with carbon or silicon carbide, and depositing on the inner wall of the crucible, a thin inner lining of silicon carbide in combination with silica, silicon nitride, and silicon nitride/alumina, or in other embodiments, amorphous carbon, boron nitride, titanium nitride or diboride, and zirconium nitride or diboride. The thin inner lining is required to avoid contamination of the molten sample, to provide a matched thermal conductivity with the molten sample, and to avoid crack propagation which is a drawback of the bulk material.

One of the most critical components in high temperature single crystal growing furnaces is the susceptor. The function of the susceptor is to hold a crucible (usually quartz in the silicon crystal growing process) which is in intimate contact with the molten material or crystal melt. The susceptor must also allow for the transfer of heat from the heater to the crystal mass. Accurate control of the thermal environment is critical to the success in fabricating high quality single crystals.

Fabrication of graphite susceptors is not trivial. The low strength characteristics of graphite and the need to support the molten mass, means that thick sections have to be used, particularly in the base of the crucible. These thick sections contribute to a high level of thermal mass and consequently, may exert an influence on the ease with which the process temperature is achieved and maintained.

In the Czochralski (CZ) process, the current, conventional CZ crystal pulling susceptor is designed to hold the quartz crucible in place during the CZ crystal pulling operation, which in turn holds the polysilicon used to make the silicon crystal. Quartz softens at approximately 1150° C.. The CZ process runs at approximately 1450° C. Consequently, the quartz crucible softens during the CZ operation and conforms to the shape of the susceptor.

The susceptor must be able to retain its shape in an argon atmosphere at reduced pressure. It must not outgas and it must be of sufficient purity not to affect the material properties of the polysilicon that is being contained by the quartz crucible. Finally, it must have the proper thermal characteristics to allow for the correct thermodynamic conditions needed to grow a silicon crystal with minimal or zero defect dislocations. The dislocations can occur from both contamination and variation in the thermodynamic conditions within the furnace.

The current conventional CZ susceptor material is graphite. Although machining of the graphite can be done to close tolerances, gaps still exist between the sections of the component. By-product gases of the crystal pulling process are highly corrosive (such as silicon monoxide in the silicon CZ process) and can attack the graphite structure through these gaps. This in turn reduces the lifetime of the components and seriously affects the crystal production rate.

The CZ silicon crystal growing process leaves some liquid silicon metal at the conclusion of crystal growth. The remaining silicon metal expands approximately 9% upon freezing. The stress induced by solidification and rapid thermal expansion of silicon in opposition to thermal contraction of the susceptor may result in the breakage of the graphite susceptor. Additionally, a single piece graphite susceptor may break upon the removal of the quartz crucible.

Another issue involved with the conventional graphite susceptor is thermal management. The conventional graphite susceptor design consists of a cylindrical upper portion, generally between 0.5″ to 1″ in thickness. The bottom portion matches the bottom contour of the quartz crucible. The periphery of the bottom portion is substantially thicker than the cylindrical upper portion. Additionally, in the furnace, the susceptor sits on a graphite base. The combined mass and volume of the graphite side walls, base, and thick bottom section of the susceptor may increase the difficulty in hot zone thermal management with respect to uniform transfer of heat through the furnace components to the crystal mass.

A crucible susceptor which avoids the disadvantages of conventional graphite crucible susceptors is disclosed in U.S. Pat. No. 5,858,486. This crucible susceptor is comprised of a high purity carbon/carbon composite material. The carbon/carbon composite susceptor is thinner than a traditional graphite susceptor, allowing for an increase in the hot zone diameter for a given fixed furnace vessel compared to the hot zone for a conventional graphite susceptor. The hot zone is the area of the furnace in which the crystal melt is contained and pulled into a uniform crystal. The larger hot zone allows for the use of a larger quartz crucible, thereby increasing the amount of polysilicon that may be pulled in a single furnace run, as well as increasing the diameter of a crystal that may be pulled. The thinner walls of the carbon/carbon composite susceptor may also provide thermal management benefits in a CZ process furnace.

While the carbon/carbon composite susceptor described above provides a high purity furnace component offering various advantages over graphite susceptors, it also has disadvantages associated with its use. One disadvantage is that a carbon/carbon composite susceptor is more expensive than a conventional graphite susceptor. Another disadvantage is that the composite susceptor is susceptible to corrosion by corrosive gases present in the CZ process furnace, due to the decreased thickness of the susceptor walls. This is especially true of the lower portions of the susceptor side walls and the base of the crucible susceptor, which are exposed to a higher temperature than the upper portion of the crucible susceptor. This higher temperature brings about greater chemical reactivity of the corrosive gases present in the furnace, which in turn causes uneven corrosion of the walls of the susceptor. Furthermore, when any one area of the susceptor becomes damaged, for example, by excessive corrosion caused by exposure to corrosive gases, the entire susceptor must be discarded.

Therefore, there is a need to develop an economical susceptor of lower thermal mass than a traditional graphite susceptor, that exhibits durability and resistance to corrosion by corrosive gases. There is likewise a need for a susceptor that may be easily repaired by replacing of parts which become excessively eroded or otherwise damaged during use, providing a longer overall life than is experienced with previously known graphite or carbon/carbon composite susceptors. There is also a need for a susceptor capable of providing a larger hot zone for a given fixed furnace vessel size compared to the hot zone provided by a traditional graphite susceptor. There is also a need for a susceptor capable of providing an increase in the hot zone for a given fixed furnace vessel or size, thus providing the CZ crystal grower with an increase in the amount of polysilicon that may be placed in an enlarged quartz crucible.

It is therefore desirable to provide a susceptor capable of providing improvement in the thermal management of the CZ furnace hot zone over traditional graphite susceptors, by providing a susceptor of lower thermal mass than traditional graphite susceptors, thus providing potential energy savings and improvement of silicon crystal quality by a reduction of crystal dislocations.

It is also desirable to provide a crucible susceptor that may be easily repaired by the replacement of parts which become excessively eroded or otherwise damaged during use, thereby providing a susceptor having a longer overall useful life than previously known carbon/carbon composite or graphite crucible susceptors.

It is further desirable to provide a susceptor capable of providing an increase in the hot zone for a given fixed furnace vessel or size, by a reduction in the susceptor side thickness compared with susceptors made solely of graphite, thus providing the CZ crystal grower with an increase in the amount of polysilicon that may be placed in an enlarged quartz crucible. Such an increase in the hot zone size could also provide for a larger crystal diameter that may be pulled in a CZ furnace of a given size.

It is also desirable to provide a susceptor capable of providing the CZ crystal grower with a susceptor of greatly increased economy, namely an ability to replace components as necessary compared both to susceptors made solely of graphite and susceptors made solely of carbon/carbon composite materials which must be replaced as a whole after localized corrosion exceeds allowances.

### BRIEF SUMMARY OF THE INVENTION

In general, the present invention provides a crucible susceptor for a crystal growing process for pulling a crystal ingot from a crystal material melt in a crucible, containing at least one high purity composite component containing a carbon fiber reinforced carbon matrix, said at least one high purity composite component having a total level of metal impurity less than about 10 parts per million, and at least one high purity graphite component, said at least one high purity graphite component having a total level of metal impurity less than about 10 parts per million. Preferably, the carbon fiber reinforcement is a two dimensional, continuously woven fabric. In one embodiment, the at least one high purity graphite component forms a lower section and the at least one high purity composite component forms an upper section.

The present invention also provides a single crystal growing process for pulling a single crystal ingot from a crystal material melt, including providing the crystal material melt in a crucible, and, intimately supporting the crucible with a crucible susceptor containing at least one high purity composite component containing a carbon fiber reinforced carbon matrix, said at least one high purity composite component having a total level of metal impurity less than about 10 parts per million, and at least one high purity graphite component, said at least one high purity graphite component having a total level of metal impurity less than about 10 parts per million.

Also provided by the present invention is a Czochralski crystal growing process for pulling a semiconductor ingot from a semiconductor material melt, including providing the semiconductor material melt in a quartz crucible, and, intimately supporting the crucible with a crucible susceptor containing at least one high purity composite component containing a carbon fiber reinforced carbon matrix, said at least one high purity composite component having a total level of metal impurity less than about 10 parts per million, and at least one high purity graphite component, said at least one high purity graphite component having a total level of metal impurity less than about 10 parts per million.

### BRIEF DESCRIPTION OF THE SEVERAL VIEWS OF THE DRAWINGS

FIG. 1 is a schematic cross sectional view of a semiconductor processing furnace, specifically a Czochralski crystal growing reactor, equipped with one embodiment of a hybrid crucible susceptor.

FIG. 2 is a schematic cross sectional view of an alternate embodiment of a hybrid crucible susceptor.

FIG. 3 is an elevational view of a hybrid crucible susceptor.

FIG. 4 is an elevational view partially broken away and in cross-section of a hybrid crucible susceptor.

FIG. 5 is an elevational view partially broken away and in cross-section of an alternate hybrid crucible susceptor.

### DETAILED DESCRIPTION OF THE INVENTION PREFERRED EMBODIMENT FOR CARRYING OUT THE INVENTION

As mentioned above, the present invention provides a crucible susceptor, also referred to herein as a hybrid crucible susceptor, containing at least one high purity carbon fiber reinforced carbon matrix material, or carbon/carbon composite component, and at least one high purity graphite component. The graphite component or components form a bottom portion of the susceptor while the composite component or components form an upper portion of the susceptor. In one embodiment, the graphite lower section extends upward and directly supports a crucible at least to the approximate point at which the inside surface of the susceptor becomes cylindrical. In such an embodiment, the carbon/carbon composite component is essentially cylindrical and preferably fits onto a graphite component as an upper sleeve to form a top portion of the side walls of the susceptor. A graphite component may include an annular lip or ledge onto which the composite component fits and which at least partially supports the composite component. The graphite components may extend upward from the base to the approximate location of the corrosion point. The corrosion point is the point at which the maximum thermal flux combines with the maximum concentration of corrosive gases to cause the most significant corrosive actions on the susceptor materials. The exact location of the corrosion point will vary according to the various conditions under which the furnace is operated, such as conditions of temperature, pressure, and crystal composition. The dimensions of the carbon/carbon composite components and/or the graphite components are preferably engineered with reference to the coefficients of expansion of the parts, such that the components become engaged at the operating temperature of the furnace. Most preferably, the components form an interference fit at the operating temperature of the furnace.

The temperature in a CZ process furnace is higher at lower portions of the furnace than at higher portions of the furnace. Therefore, the lower portion of the crucible susceptor is exposed to corrosive gases at a higher temperature than the upper portion of the susceptor. Consequently, the lower portion of the susceptor experiences a greater amount of corrosion than the upper portion of the susceptor, due to the greater chemical activity of the corrosive gases at the higher temperature. Because of the greater thickness and density of graphite components used in the lower portion of the susceptor, compared to carbon/carbon composite components, the susceptor of the present invention is capable of withstanding a greater amount of corrosion than the prior carbon/carbon composite susceptor. Furthermore, the carbon/carbon composite component and/or the graphite components of the present invention can be removed to be cleaned or replaced. Due to the greater corrosion of lower portions of the composite component as mentioned above, the lower portion of the composite component should experience more corrosion over the life of the part than the upper portion. When the carbon/carbon composite component is essentially cylindrical, it may also be periodically inverted on the graphite portion of the susceptor. When the composite component is inverted on the graphite lower portion after a number of uses, the overall life of the component is extended by exposing the more heavily corroded area of the component to less reactive gases near the top of the susceptor and the less heavily corroded area to more reactive gases closer to the base of the susceptor.

Other embodiments of the crucible susceptor of the present invention are also envisioned. In one such embodiment, the graphite component forms a bottom portion of the susceptor while the composite component forms an upper portion of the susceptor, as mentioned above. In this embodiment however, the graphite component does not extend upward to such an extent as to be able to directly support the side walls of a crucible. The graphite component also has a protruding portion which extends from the upper surface of the graphite component. The protruding portion of the graphite component is preferably located at or near the center of the graphite component. The carbon/carbon composite component in such a susceptor will be cup-shaped or at least curved, with an aperture or orifice preferably located at the portion of the component corresponding to the bottom of a cup or curve. In this example, the composite component can directly support a portion of the base of the crucible as well as the side walls of the crucible. In such a susceptor, the carbon/carbon composite component preferably fits on top of and is at least partially supported by the graphite component, with the protruding portion of the graphite component mating with the aperture or orifice of the composite component. The protruding portion is preferably engineered to extend from the remainder of the graphite component a distance essentially equal to the thickness of the composite component, such that when the composite component is engaged on the graphite component, the inner surface of the susceptor presents an essentially smooth, even face at the operating temperature of the furnace. In this way, both the protruding portion of the graphite component and the composite component directly support the bottom of the crucible. As mentioned above, the graphite and carbon/carbon composite components are preferably engineered with reference to the coefficients of expansion of the parts, such that the two components form a close fit, preferably an interference fit, at the operating temperature of the furnace.

Carbon fiber reinforced carbon matrix materials, or carbon/carbon composites, have thermal stability, high resistance to thermal shock due to high thermal conductivity and low thermal expansion behavior (that is, thermal expansion coefficient or TEC), and have high toughness, strength and stiffness in high-temperature applications. Carbon/carbon composites comprise carbon reinforcements mixed or contacted with matrix precursors to form a “green” composite, which is then carbonized to form the carbon/carbon composite. They may also comprise carbon reinforcements in which the matrix is introduced fully or in part by chemical vapor infiltration.

The carbon reinforcements are commercially available and can take the form of continuous fiber, cloth or fabric, yarn, and tape (unidirectional arrays of fibers). Yarns may be woven in desired shapes by braiding or by multidirectional weaving. The yarn, cloth and/or tape may be wrapped or wound around a mandrel to form a variety of shapes and reinforcement orientations. The fibers may be wrapped in the dry state or they may be impregnated with the desired matrix precursor prior to wrapping, winding, or stacking. Such prepreg and woven structures reinforcements are commercially available from Hitco Carbon Composites, Inc. The reinforcements may be prepared from precursors such as polyacrylonitrile (PAN), rayon or pitch. According to one embodiment of the present invention, the reinforcement may be in the form of woven cloth, such as a two dimensional, continuously woven carbon fiber. In another embodiment, the reinforcement is formed by filament winding before or after impregnation with a matrix precursor.

Matrix precursors which may be used to form carbon/carbon composites according to the present invention include liquid sources of high purity (that is, semiconductor quality) carbon, such as phenolic resins and pitch, and gaseous sources, including hydrocarbons such as methane, ethane, propane and the like.

The carbon/carbon composites useful in the present invention may be fabricated by a variety of techniques. Conventionally, resin impregnated carbon fibers are autoclave- or press-molded into the desired shape on a tool or in a die. The molded parts are heat-treated in an inert environment to temperatures from about 700° C. to about 2900° C. in order to convert the organic phases to carbon. The carbonized parts are then densified by carbon chemical vapor impregnation or by multiple cycle reimpregnations with the resins described above. Other fabrication methods include hot-pressing and the chemical vapor impregnation of dry preforms. Methods of fabrication of carbon/carbon composites which may be used according to the present invention are described in U.S. Pat. Nos. 3,174,895 and 3,462,289, which are incorporated by reference herein.

Shaped carbon/carbon composite parts for semiconductor processing components can be made either integrally before or after carbonization, or can be made of sections of material joined into the required shape, again either before or after carbonization.

Once the general shape of the carbon/carbon composite article is fabricated, the piece can be readily machined to precise tolerances, on the order of about 0.1 mm or less. Further, because of the strength and machinability of carbon/carbon composites, in addition to the shaping possible in the initial fabrication process, carbon/carbon composites can be formed into shapes for components that are not possible with graphite.

The at least one high purity carbon/carbon composite according to the present invention has the properties of conventionally produced carbon/carbon composites, yet has improved purity resulting from the process for the production of a semiconductor standard composite of the present invention.

According to the inventive process, fiber (reinforcement) purity may be enhanced by the carbon fiber reinforcement being heat treated in a non-oxidizing (inert) atmosphere to a temperature of about 2400° C. (4350° F.) to about 3000° C. to remove impurities. This heat treatment further sets the reinforcements, avoiding shrinkage in later procedures.

Carbon matrix purity is enhanced by the utilization of high purity matrix precursors in the impregnation of the heat treated carbon reinforcement. The purity level of the carbon sources should be less than about 50 ppm metals. For example, the phenolic resins should contain less than about 50 ppm metals, should utilize non-metallic accelerators for cure, and preferably should be made in a stainless steel reactor.

The impregnated reinforcements, or prepregs, are staged, laid-up, cured and carbonized (or pyrolized) conventionally, except that processing conditions are maintained at semiconductor standards. The carbonized part is then densified by chemical vapor impregnation or liquid pressure impregnation, using the carbon source materials mentioned above.

In the chemical vapor deposition (CVD) densification of the carbonized part, precautions are taken not to introduce any elemental impurities in the CVD furnace. Prior to processing the carbonized parts, the furnace may be purged by running an inert gas, such as argon, helium or nitrogen, through it for several heat treat cycles at about 2400° C. to about 3000° C.

After the component has been formed by the densification of the carbonized part, the component is further heat treated at 2400° C. to about 3000° C. in a non-oxidizing or inert atmosphere to ensure graphitization of the structure and to remove any impurities that may have been introduced. The period of time for this procedure is calculated based upon graphitization time/temperature kinetics, taking into account furnace thermal load and mass. The component may be machined, if desired, to precise specifications and tolerances, as discussed above.

In a further purification procedure, the heat treated components may be further heat treated at 2400° C. to about 3000° C. in a halogen atmosphere to remove any remaining metallic elements as the corresponding volatile halides. Suitable halogens include fluorine, chlorine, and bromine, with chlorine being preferred. The purification treatment may be terminated when no metallic species are detected in the off-gas.

High purity graphite components are produced by a technique that is well known in the art. Graphite components are fabricated and subsequently exposed to temperatures between about 1800° C. and about 2500° C. in a halogen atmosphere to remove any remaining metallic elements as the corresponding volatile halides. Suitable halogens include fluorine, chlorine, and bromine, with chlorine being preferred. The purification treatment may be terminated when no metallic species are detected in the off-gas.

Throughout the production process, great care is taken not to contaminate any parts. As discussed above, processing is performed to semiconductor standards, including the use of laminar air flow in work areas which ensure ISO 9000 conditions.

High purity carbon/carbon composites prepared according to the present invention were analyzed by inductively coupled plasma spectroscopy (ICP) in comparison with conventional graphite components, the latter of which was also analyzed by atomic absorption spectroscopy (AAS). The results are shown in Table I below.

TABLE I

| | | | High Purity C/C |
|---|---|---|---|
| Element (ppm) | Graphite (1) | Detection Limit (2) | Level (2) |
| Aluminum | <0.08 | 0.1 | ND |
| Calcium | 0.13 | 0.1 | ND |
| Chromium | <0.07 | 0.01 | ND |
| Copper | <0.08 | 0.02 | ND |
| Iron | 0.09 | 0.04 | 0.18 |
| Magnesium | <0.02 | 0.02 | ND |
| Manganese | <0.08 | 0.01 | ND |
| Nickel | <0.10 | 0.04 | ND |
| Potassium | <0.10 | 4 | ND |
| Sodium | <0.05 | 0.2 | ND |
| Vanadium | <0.07 | 0.02 | 0.24 |

(1) by ICP, AAS
(2) by ICP
ND-Not Detected

High purity carbon/carbon composites prepared according to the present invention were analyzed by inductively coupled plasma spectroscopy in comparison with conventional carbon/carbon composites, the latter of which was analyzed by high temperature halonization, and the results are shown in Table II below.

TABLE II

| | Conventional | | High Purity C/C |
|---|---|---|---|
| Element (ppm) | C/C (1) | Detection Limit (2) | Level (2) |
| Aluminum | 4 | 0.1 | ND |
| Calcium | 10-30 | 0.1 | ND |
| Chromium | <0.32 | 0.01 | ND |
| Copper | <0.06 | 0.02 | ND |
| Iron | 3-5 | 0.04 | 0.18 |
| Magnesium | 3-5 | 0.02 | ND |
| Manganese | 0.034 | 0.01 | ND |
| Molybdenum | 1 | 0.02 | ND |
| Nickel | ND | 0.04 | ND |
| Phosphorous | 5.8 | 0.02 | ND |
| Potassium | ND | 4 | ND |
| Sodium | 4.8 | 0.2 | ND |

(1) by High Temperature Halonization
(2) by Inductively Coupled Plasma Spectroscopy (ICP)
ND = Not Detected

As shown in Tables I and II, the high purity carbon/carbon composites of the present invention are below the detection limit for inductively coupled plasma spectroscopy analysis for the metals Al, Ca, Cr, Cu, K, Mg, Mn, Mo, Na, Ni, and P. Metal impurities are shown to be present in graphite, but at levels that are below 0.14 ppm for all metals tested, below 0.1 ppm for Al, Cr, Cu, Fe, K, Mg, Mn, Na, Ni, and, V, and below the detection limit by Inductively Coupled Plasma Spectroscopy for Al, Mg and Na. Metal impurities are also found in conventional carbon/carbon composite materials (except for nickel and potassium).

Carbon/carbon composites produced according to the invention were ashed and the diluted residue further analyzed by inductively coupled plasma spectroscopy for metals content in addition to those metals tested above. As demonstrated in Table III below, the concentration of these metals, Ag, Ba, Be, Cd, Co, Pb, Sr, and Zn, was also below the detection limit for the analytical technique.

TABLE III

| | | HIGH PURITY C/C |
|---|---|---|
| ELEMENT | DETECTION LIMIT (PPM) | LEVEL |
| Barium | 0.01 | ND |
| Beryllium | 0.01 | ND |
| Cadmium | 0.01 | ND |
| Cobalt | 0.02 | ND |
| Lead | 0.2 | ND |
| Silver | 0.02 | ND |
| Strontium | 0.02 | ND |
| Zinc | 0.02 | ND |

ND = Not Detected

Hybrid susceptor components, according to the invention, can be used in semiconductor processing without first coating the component, although it is preferable to precoat the components prior to use, in order to lock down any particles which may have formed as a result of the composite fabrication or machining process. A coating may be desired in the event of a change in the process furnace atmosphere. Components can readily be coated with a protective refractory coating, such as refractory carbides, refractory nitrides, and, particularly with regard to components to be used in the production of gallium arsenide crystals, refractory borides. Preferred refractory coatings are silicon carbide, silicon nitride, boron nitride, pyrolytic boron nitride and silicon boride. Graded or layered coatings of the carbides, nitrides and borides may also be used.

Advantages of hybrid crucible susceptors over both carbon/carbon (C/C) composite and traditional graphite susceptors, particularly with regard to semiconductor processing such as in the semiconductor crystal growing process furnace, arise from two factors. The first is the ability to distribute corrosion evenly over the C/C composite component or components. The second is the greater thickness and density, and therefore overall resistance to corrosion, of the graphite component or components in comparison to one piece C/C susceptors. The graphite components of the hybrid crucible susceptor are exposed to more chemically reactive high temperature corrosive gases than the C/C composite components.

The high purity, semiconductor standard carbon/carbon composite components of the present invention can be produced to exhibit a density of about 1.6 to about 2 g/cc, and a porosity of about 2 to about 25%. These high purity composites generally range in tensile strength from about 25 to about 100 ksi, in tensile modulus from about 3 to about 30 msi, in flexural strength from about 15 to about 60 ksi, in compressive strength from about 10 to about 50 ksi, and in fractural toughness as measured by Izod impact, about 5 to about 25 ft-lb/in.

Such high purity composite components exhibit a thermal conductivity of about 20 to about 500 W/mK in plane and about 5 to about 200 W/mK cross-ply, and thermal expansion coefficients (CTE) of zero to about 2×10⁻⁶ m/° C. in plane and about 6×10⁻⁶ m/m/° C. to about 10×10⁻⁶ m/m/° C. cross ply. Thermal emissivity of the high purity composites is about 0.4 to about 0.8. The electrical resistivity of the high purity composites is about 1×10⁻⁴ to about 1×10⁻² ohm-cm.

High purity graphite components display similar properties when compared to high purity carbon/carbon composite components. The high purity graphite components typically have a flexural strength of about 8 to about 9 ksi, a compressive strength of about 15 to about 20 ksi, a fracture toughness as measured by Izod impact of about 1 ft lb/in, a thermal expansion coefficient of about 2×10⁻⁶ m/m/° C. and about 10×10⁻⁶ m/m/° C., an in-plane thermal conductivity of about 70 to about 130 W/mK, a thermal emissivity of about 0.5 and about 1.0, and an electrical resistivity of about 1.2×10⁻³ to about 2.2×10⁻³ ohm-cm. High purity carbon/carbon composite and graphite components used in the present invention were produced and exhibited the properties demonstrated in Table IV below.

TABLE IV

| | | CARBON/ | |
|---|---|---|---|
| | | CARBON | |
| PROPERTY | UNITS | COMPOSITE | GRAPHITE |
| Density | g/cc | 1.65 − 1.75 | 1.70 − 1.85 |
| Melt Point* | ° C. | 3650 | 3660 |
| Tensile Strength | Ksi | 35 | 1.3 |
| Tensile Modulus | Msi | 16 | 1.2 |
| Flexural Strength | Ksi | 25 | 7.5 |
| Compressive Strength | Ksi | 30 | 13 |
| Fracture Toughness | Izod ft lb/in | 13 | 1 |
| CTE-with ply | m/m/° C. | 1.4 × 10⁶ | 3.3 − 5.3 × 10⁶ |
| CTE-across ply | m/m/° C. | 6.3 × 10⁶ | NA |
| Thermal Conductivity | W/mK | 50 − 160 | 70 − 130 |
| Porosity | % | 8 | 10 − 18 |
| Thermal Emissivity | | 0.52 | 0.77 |
| Resistivity @ | Ω-cm | 0.0010 | 0.0012 − 0.0022 |
| 1500° C. | | | |

*Sublimation Temperature

According to the present invention, the high purity, semiconductor standard carbon/carbon composites are formed into an upper portion of a crucible susceptor. These components are useful in the Czochralski crystal growing furnace for producing semiconductor crystals of silicon, as well as other semiconductor materials such as gallium arsenide and cadmium zinc telluride, by pulling a crystal from a semiconductor melt.

According to the invention therefore, Czochralski process furnace crucible susceptors have been fabricated, comprising at least one high purity, semiconductor standard composite component including a carbon fiber reinforced carbon matrix, and at least one high purity, semiconductor standard graphite component, both of which have a total level of metal impurity below about 10 ppm, preferably below about 5 ppm, and more preferably having a level of metal impurity below 0.14 ppm for the metals Al, Ca, Cr, Cu, Fe, K, Mg, Mn, Na, Ni, V. More preferably, the graphite and carbon/carbon composite components have a metal impurity level below 0.1 ppm for Al, Cr, Cu, Fe, K, Mg, Mn, Na, Ni, and, V. Most preferably, the graphite and carbon/carbon composite components have a metal impurity level below the detection limit of inductively coupled spectroscopy for the metals for Al, Mg and Na.

The high purity hybrid susceptors have been used in the Czochralski crystal growing process for pulling a silicon ingot from a silicon melt. In this process, the silicon melt was formed in a quartz crucible, which was intimately supported within the furnace by the susceptor.

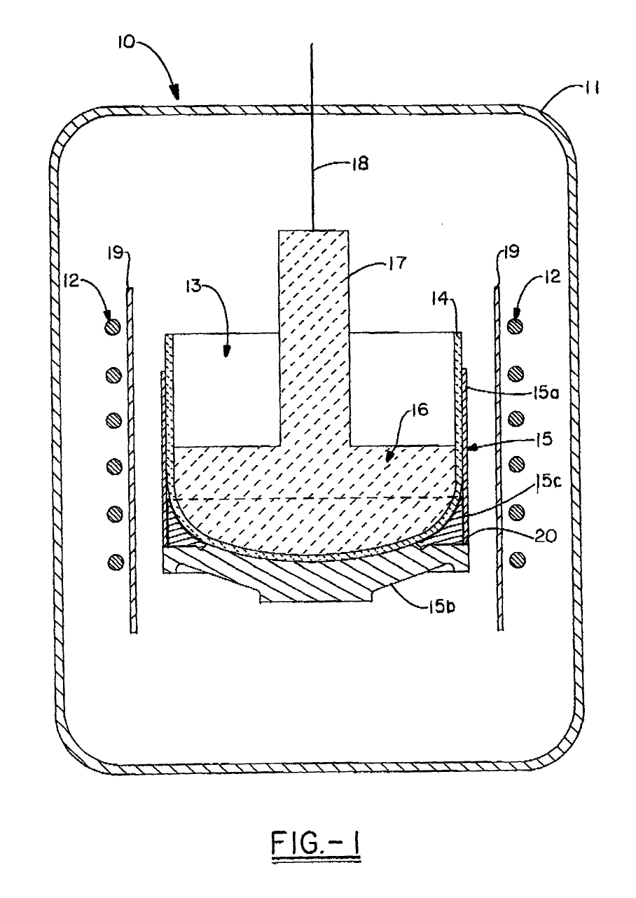

As shown in the sectional schematic of FIG. 1, a typical Czochralski semiconductor processing reactor comprises a furnace 10 having a water jacketed stainless steel wall 11 to enclose the processing area. Insulation, not shown, protects the wall from the internal heating elements 12. Disposed radially inwardly of heating elements 12 is the crystal- or ingot-pulling zone 13, where the semiconductor material is melted and processed.

Within crystal pulling zone 13, a crucible 14, suitably made of quartz, is intimately supported by a high purity hybrid crucible susceptor 15 which rests either on a refractory hot surface, insulation, an axle for rotation of the crucible susceptor 15, or another furnace component (not shown). An upper portion 15a of hybrid crucible susceptor 15 is comprised of a high purity carbon/carbon composite material, while a base 15b of hybrid crucible susceptor 15 is comprised of a high purity graphite material. A sealing member 15c is also comprised of a high purity graphite material. The semiconductor material is heated within the crucible 14 to form a melt 16, from which a crystal or ingot 17 is drawn by conventional crystal drawing means 18, such as a weighted pulley. The semiconductor material is highly pure, electronic quality silicon or gallium arsenide. The crystal pulling zone 13 may be maintained at a subatmospheric pressure, by means for evacuating the furnace (not shown).

As shown in FIG. 1, outside heating elements 12 and crystal pulling zone 13 is disposed a furnace heat shield or furnace tube liner 19, comprising high purity graphite or carbon/carbon composite. Crucible susceptor 15, and particularly heat shield or tube liner 19, protect crystal pulling zone 13 and melt 16 and crystal 17 contained therein from potentially contaminating elements. Alternatively, a heat shield can be disposed radially outside of the heating elements in order to contain heat within the crystal pulling zone and prevent its dissipation radially (not shown).

These high purity composite components provide a stable thermal environment in which the solidification of crystal or ingot 17 is permitted to proceed without non-uniformity causing thermal excursions. Heat shield 19 as shown in FIG. 1, helps to maintain crystal pulling zone 13 at an optimum temperature for the semiconductor material being processed such as about 1450° C. for silicon, even though the outer surface of the shield, exposed to the heating elements 12, may experience a much higher temperature such as 1500° C. to 2000° C. Crucible susceptor 15 intimately supports the crucible 14, which may soften and begin to “flow” at operating temperatures. The susceptor 15 maintains the structural integrity of the crucible 14 during operation.

As shown in FIG. 1, susceptor 15 comprises an upper portion 15a, a base 15b and a sealing member 15c. Base 15b and sealing member 15c are graphite while upper portion 15a is carbon/carbon composite. The graphite components form a structure which curves upward to approximately the point at which the inside surface becomes cylindrical, forming a lower portion of the inner side walls of the susceptor. In this example, upper portion 15a preferably fits onto base 15b as an upper sleeve to form a top portion of the side walls of the susceptor. Base 15b may be engineered to include an annular ledge 20, such that upper portion 15a rests on and is at least partially supported by annular ledge 20 of base 15b. Annular ledge 20 may also be engineered to engage a sealing member 15c. Alternately, the structures formed by base 15b and sealing member 15c may be engineered as a single piece (not shown). Upper portion 15a, base 15b, and sealing member 15c are preferably engineered with reference to the coefficients of expansion of the parts, such that upper portion 15a, base 15b, and sealing member 15c become closely engaged at the operating temperature of the furnace, most preferably, forming an interference fit at the operating temperature of the furnace. According to this example, crucible 14 is directly supported by upper portion 15a, base 15b, and sealing member 15c. In the course of operation of furnace 10 containing susceptor 15, deposits of silicon carbide or other compounds may form on sealing member 15c. As these deposits continue to form, they may alter the close tolerance between sealing member 15c and upper portion 15a. If these alterations become great enough, stress may be placed on the components of susceptor 15 during operation of the furnace, possibly resulting in the introduction of cracks into base 15b or sealing member 15c. Therefore, sealing member 15c may be removed after one or more uses for cleaning or replacement.

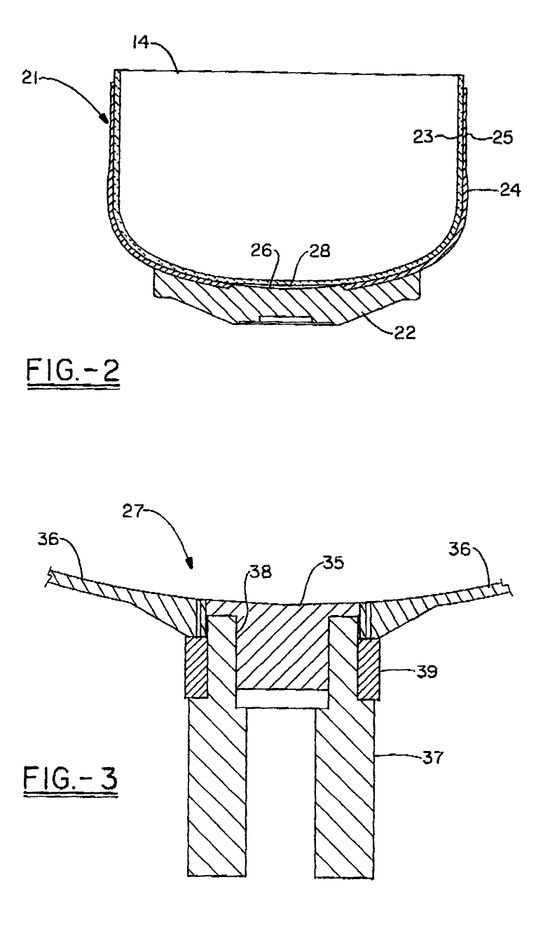

FIG. 2 shows an alternative design for a hybrid crucible susceptor 21. Susceptor 21 has an inner surface 23 and an outer surface 25. In this embodiment, susceptor 15 comprises a base 22 and an upper portion 24. Base 22 of susceptor 21 is comprised of graphite. Upper portion 24 of susceptor 21 is comprised of carbon/carbon composite material. Base 22 also has a protruding member 26 which extends upward from the surface of base 22. Protruding member 26 is preferably located at or near the center of base 22. When assembled in susceptor 21, protruding member 26 of base 22 directly supports at least a portion of crucible 14. Upper portion 24 is cup-shaped or curved, with an aperture or orifice 28 preferably located in the region of upper portion 24 that corresponds to the bottom of a cup or curve. In such an embodiment, upper portion 24 fits on top of and is at least partially supported by base 22, with protruding member 26 mating with aperture or orifice 28. Protruding member 26 is preferably engineered to extend upward from the remainder of base 22 a distance essentially equal to the thickness of upper portion 24 adjacent to orifice 28 such that protruding member 26 completes the arc of an inner surface of upper portion 24 interrupted by orifice 28. In such an embodiment, when upper portion 24 is engaged on base 22, upper portion 24 and base 22 present an essentially unitary inner surface 23 of susceptor 21 at the operating temperature of the furnace. Stated another way, when assembled and at the operating temperature of a crystal pulling process, the susceptor preferably has an inner surface that is essentially smooth and uninterrupted. As in the previously described embodiment, base 22 and upper portion 24 are preferably engineered with reference to the coefficients of expansion of the parts, such that the two components become closely engaged, most preferably forming an interference fit, at the operating temperature of the furnace. In this way, crucible 14 is directly supported by both protruding member 26 of base 22 and upper portion 24 of susceptor 15. Susceptor outer surface 25 may taper in such a way that upper portion 24 is thicker at or near its top edge than it is adjacent to orifice 28. Such a configuration provides susceptor 21 with greater thickness in those regions susceptible to greater corrosion.

FIG. 3 shows an alternative design for a hybrid crucible susceptor 27. In this embodiment, susceptor 27 comprises a plug base 35 and an upper portion 36. Plug base 35 is comprised of graphite. Upper portion 36 is comprised of high purity carbon/carbon composite material. Upper portion 36 is cup-shaped or curved, with an aperture or orifice 38 preferably located in the region of upper portion 24 that corresponds to the bottom of a cup or curve. Upper portion 36 fits on top of a pedestal 37 or other supporting device, either directly (not shown) or indirectly by resting on a pedestal spacer 39 which rests on pedestal 37. Plug base 35 directly fits onto pedestal 37. The dimensions of pedestal 37, plug base 35 and upper portion 36 are preferably engineered such that plug base 35 completes the arc of an inner surface of upper portion 36 interrupted by orifice 38. In this way, when susceptor 27 is assembled, it presents an essentially unitary inner surface to a crucible at a temperature at which a crystal ingot is pulled. As in previous embodiments, pedestal 37, plug base 35 and upper portion 36 of susceptor 27 are preferably engineered with reference to the coefficients of expansion of the parts, such that the components become engaged at the operating temperature of the furnace, preferably forming an interference fit.

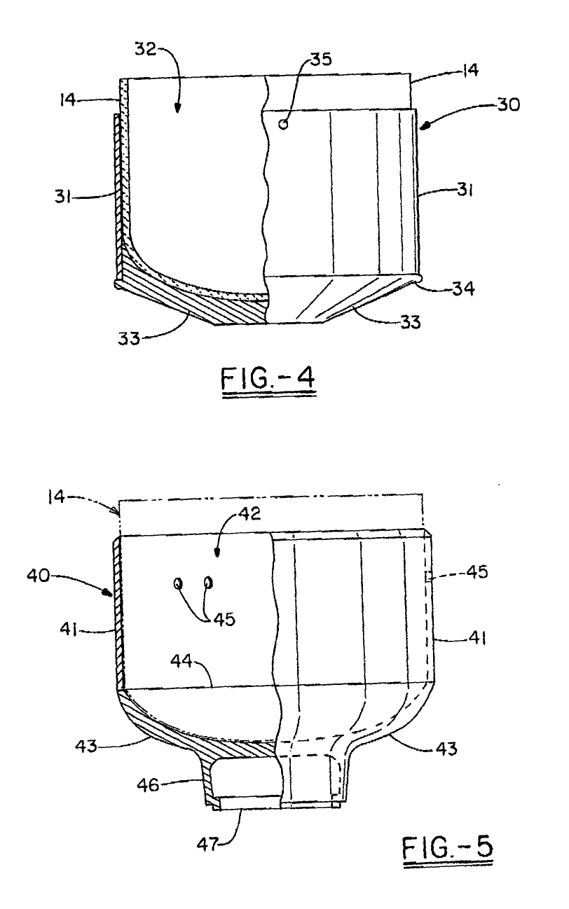

As shown in FIG. 4, the crucible susceptor 30 has a high purity composite upper side wall 31, a top opening 32 and a high purity graphite base 33. The interior of the crucible susceptor 30 is shaped to hold the particular crucible design for which it was intended, and thus the base 33 can be scooped in the form of a bowl and can optionally contain a ridge 34 such as for nesting the crucible. Upper side wall 31 may contain fixturing holes 35 for mounting the susceptor 30.

In an alternative embodiment shown in FIG. 5, the crucible susceptor 40 also has a high purity composite upper side wall 41, a top opening 42 and a high purity graphite base 43. Base 43 may also be scooped, and base 43 and side wall 41 may optionally contain one or more ridges 44. Fixturing holes 45 may be present in the side wall 41. The base 43 can contain a high purity composite or graphite fitting 46 which defines an engagement zone 47 that may engage an axle for rotating the crucible/crucible susceptor assembly, an exhaust tubing for lowering the pressure of the furnace interior, or another furnace component. The ease of fabrication of the high purity carbon/carbon composite materials prior to carbonization, and their machinability after carbonization, permits the fabricating the furnace components into any desired configuration.

The present invention also provides a single crystal growing process for pulling a single crystal ingot from a crystal material melt. According to this process, the hybrid crucible susceptor, as described above, is used to intimately support a crucible which contains a crystal material melt. The crystal material may be sapphire, silicon, gallium arsenide, or cadmium zinc telluride, for example. Also according to the present invention, the hybrid crucible susceptor may be utilized in a Czochralski crystal growing process for pulling a semiconductor ingot from a semiconductor material melt. In such a process, the semiconductor material may be silicon, gallium arsenide, or cadmium zinc telluride.

Use of the hybrid susceptor according to the process of present invention provides the following improvements for the crystal grower, in the CZ process and related single crystal pulling operations. The crucible can be completely contained, eliminating the need for additional spill containment resources. Thermal management of the crystal growing furnace hot zone is improved, thus providing energy savings and improvement of crystal quality by a reduction of crystal dislocations. The effective size of the hot zone for a given fixed furnace vessel or furnace size is increased, by a reduction in the susceptor side thickness, thus providing an increase in the amount of crystal growing melt, such as polysilicon, which can be placed in the correspondingly enlarged quartz crucible. The hybrid susceptor has a greatly increased lifetime relative to conventional graphite susceptors and carbon/carbon composite susceptors, due to an increased number of heating and cooling cycles which the hybrid susceptor can tolerate prior to replacement.

The carbon/carbon susceptor component of the present invention is preferably fabricated with a two dimensional, continuously woven carbon fiber fabric. This continuous fiber, ply lay-up structure provides a susceptor having over ten times the physical properties of the existing graphite components. Additionally, carbon/carbon susceptor components do not exhibit catastrophic failures under elevated temperature conditions in an argon atmosphere.

The dimensions of the carbon/carbon susceptor upper section and graphite susceptor lower section are configured with regard to the coefficients of expansion of the two materials such that the upper section and the lower section fit closely together at the operating temperature of a crystal pulling furnace such as a CZ process furnace.

The increase in furnace hot zone achieved according to the present invention is directly derived from the reduction in the susceptor side ring thickness. The carbon/carbon susceptor component thickness preferably ranges from about 3 mm up to about 9 mm. This is a total reduction in part thickness over graphite of about 50 percent up to about 85 percent. The corresponding difference between the hybrid susceptor and graphite susceptor part thickness translates into a 25 to 50 mm increase in hot zone size. This means that a single crystal grower can increase its capacity by up to 24%. This can also allow for the production of crystals with a larger diameter than would otherwise be possible with a conventional graphite susceptor.

The decreased mass of the components of the present invention compared to graphite susceptors provides a faster heat-up and cool-down times for a crystal pulling furnace equipped with the susceptor of the present invention.

The following further advantages have been realized using the high purity composite components of the present invention in the CZ crystal growing apparatus. The improved durability of the hybrid susceptor results in a reduction in furnace downtime. The hybrid susceptor of the present invention may provide a typical lifetime improvement of 110 to 150 percent, compared to prior susceptors. The durability of the high purity carbon/carbon composite components is due to their superior thermal and mechanical properties.

The use of high purity carbon/carbon composite components in the CZ crystal growing reactor results in significant improvements in the yield of silicon wafers that are classified as “good for structure”. The yield of “good for structure” wafers produced with graphite furnace components was 68 percent, while the yield of “good for structure” wafers produced with hybrid furnace components was 72 percent. It should be noted that in the silicon semiconductor wafer manufacturing industry, a 1 percent increase in yield is regarded as extremely financially significant. This difference in good for structure yield may be attributable to the superior control of thermal conductivity throughout the high purity carbon/carbon composite components over time. Very little degradation of thermal properties of the inventive materials was observed. It is envisioned that silicon material produced using the susceptor of the present invention will exhibit a minority carrier lifetime of greater than 400 microseconds.

Regarding power consumption, the electrical power required by a CZ furnace equipped with hybrid components was significantly less than that of a similar furnace equipped with conventional graphite parts. This is due to the superior thermal characteristics of the high purity carbon/carbon composite components, as shown above. This power savings is very significant, in terms of capital requirements as well as operating costs.

Therefore, the present invention provides the production and use of hybrid crucible susceptors comprising graphite and carbon/carbon composite components for use in semiconductor processing. The cost and durability advantages of the inventive susceptor with respect to graphite and carbon/carbon composite susceptors have been demonstrated, as shown above. It should be understood that the present invention is not limited to the specific embodiments described above, but includes the variations, modifications and equivalent embodiments that are defined by the following claims.

We claim:

1. A crucible susceptor for a crystal growing process for pulling a crystal ingot from a crystal material melt in a crucible, comprising:
at least one high purity composite component containing a carbon fiber reinforced carbon matrix, said at least one high purity composite component having a total level of metal impurity less than about 10 parts per million; and
at least one high purity graphite component, said at least one high purity graphite component having a total level of metal impurity less than about 10 parts per million.

2. The crucible susceptor of claim 1, wherein the carbon matrix is reinforced with a two dimensional, continuously woven carbon fiber fabric.

3. The crucible susceptor of claim 1, wherein the crucible susceptor comprises a lower section and an upper section, wherein the at least one high purity graphite component comprises the lower section and the at least one high purity composite component comprises the upper section.

4. The crucible susceptor of claim 3, wherein the upper section is essentially cylindrical and wherein the upper section fits onto the lower section as an upper sleeve to form a top portion of the side walls of the susceptor.

5. The crucible susceptor of claim 3, wherein the lower section extends upward at least to the point at which an inside surface of the susceptor becomes cylindrical.

6. The crucible susceptor of claim 3, wherein the upper section and the lower section of the crucible susceptor form an interference fit at a temperature at which a crystal ingot is pulled.

7. The crucible susceptor of claim 1, additionally comprising a refractory coating selected from the group consisting of carbides, borides, and nitrides.

8. The crucible susceptor of claim 1, additionally comprising a refractory coating selected from the group consisting of silicon carbide, silicon nitride, boron nitride, pyrolytic boron nitride and silicon boride.

9. The crucible susceptor of claim 1 wherein said metal impurity is selected from the group consisting of Al, Ca, Cr, Cu, Fe, K, Mg, Mn, Na, Ni, V and mixtures thereof.

10. The crucible susceptor of claim 1 wherein the at least one high purity composite component and the at least one high purity graphite component have a total level of metal impurity less than about 5 parts per million.

11. The crucible susceptor of claim 1 wherein the at least one high purity composite component and the at least one high purity graphite component have a level of metal impurity for any one metal less than about 0.14 parts per million.

12. The crucible susceptor of claim 1 wherein the at least one high purity composite component has at least one property selected from the group consisting of:
a flexural strength of greater than or equal to about 15 ksi;
a compressive strength of greater than or equal to about 10 ksi;
a fracture toughness as measured by Izod impact of greater than or equal to about 5 ft lb/in;
an in-plane thermal expansion coefficient of zero to about 6×10⁻⁶ m/m/° C.;
a cross-ply thermal expansion coefficient of about 6×10⁻⁶ m/m/° C. and about 10×10⁻⁶ m/m/° C.;
an in-plane thermal conductivity of about 20 to about 500 W/mK;
a cross-ply thermal conductivity of about 5 to about 200 W/mK;
a thermal emissivity of about 0.4 and about 0.8;
an electrical resistivity of about 1×10⁻⁴ to about 1×10⁻² ohm-cm.

13. The crucible susceptor of claim 1 wherein the at least one high purity graphite component has at least one property selected from the group consisting of:
a flexural strength of greater than or equal to about 8 ksi;
a compressive strength of greater than or equal to about 15 ksi;
a fracture toughness as measured by Izod impact of greater than or equal to about 1 ft lb/in;
a thermal expansion coefficient of about 2×10⁻⁶ m/m/° C. and about 10×10⁻⁶ m/m/° C.;
an in-plane thermal conductivity of about 70 to about 130 W/mK;
a thermal emissivity of about 0.5 and about 1; and
an electrical resistivity of about 1.2×10⁻³ to about 2.2×10⁻³ ohm-cm.

14. The crucible susceptor of claim 1, wherein the at least one high purity composite component forms a cup-shaped upper section, said upper section having an orifice located in the region of the upper section corresponding to the bottom of a cup, wherein the at least one high purity graphite component forms a base of the susceptor, said base being shaped in such a way that a portion of said base engages said orifice and said upper section and said lower section form an interference fit at an operating temperature of a crystal growing process.

15. The crucible susceptor of claim 14, wherein the susceptor has an inner surface and wherein the portion of the base which engages said orifice completes the arc of the inner surface of the upper portion interrupted by said orifice, such that the inner surface of the crucible susceptor is essentially smooth and uninterrupted.

16. The crucible susceptor of claim 15 wherein the thickness of the upper section tapers upwardly such that the upper section is thinner at a top edge than it is adjacent to the orifice.

17. A single crystal growing process for pulling a single crystal ingot from a crystal material melt, comprising:
providing a crystal material melt in a crucible, and,
intimately supporting the crucible with a crucible susceptor containing at least one high purity composite component containing a carbon fiber reinforced carbon matrix, said at least one high purity composite component having a total level of metal impurity less than about 10 parts per million, and at least one high purity graphite component, said at least one high purity graphite component having a total level of metal impurity less than about 10 parts per million.

18. The process of claim 17, wherein the high purity composite component contains a carbon matrix reinforced with a two dimensional, continuously woven carbon fiber fabric reinforcement.

19. The process of claim 17, wherein the crystal material is selected from the group consisting of sapphire, silicon, gallium arsenide and cadmium zinc telluride.

20. The process of claim 17, wherein the crucible susceptor comprises a lower section and an upper section, wherein the at least one high purity graphite component comprises the lower section and the at least one high purity composite component comprises the upper section.

21. The process of claim 20, wherein the lower section extends upward at least to the point at which the inside surface of the susceptor becomes cylindrical.

22. The process of claim 20, wherein the upper section and the lower section of the crucible susceptor form an interference fit at a temperature at which a crystal ingot is pulled.

23. A Czochralski crystal growing process for pulling a semiconductor ingot from a semiconductor material melt, including:
providing the semiconductor material melt in a quartz crucible, and,
intimately supporting the crucible with a crucible susceptor containing at least one high purity composite component containing a two dimensional, continuously carbon fiber reinforced carbon matrix, said at least one high purity composite component having a total level of metal impurity less than about 10 parts per million, and at least one high purity graphite component, said at least one high purity graphite component having a total level of metal impurity less than about 10 parts per million.

24. The process of claim 23, wherein the semiconductor material melt is selected from the group consisting of silicon, gallium arsenide and cadmium zinc telluride.

25. The process of claim 23, wherein the crucible susceptor comprises a lower section and an upper section, wherein the at least one high purity graphite component comprises the lower section and the at least one high purity composite component comprises the upper section.

26. The process of claim 25, wherein the lower section extends upward at least to the point at which the inside surface of the susceptor becomes cylindrical.

27. The process of claim 25, wherein the upper section and the lower section of the crucible susceptor form an interference fit at a temperature at which a semiconductor ingot is pulled.
